(19) United States
(12) Patent Application Publication
(10) Pub. No.: US 2015/0087208 A1
(43) Pub. Date: Mar. 26, 2015

(54) APPARATUS AND METHOD FOR MANUFACTURING A SEMICONDUCTOR WAFER

(71) Applicant: TAIWAN SEMICONDUCTOR MANUFACTURING COMPANY, LTD., Hsinchu (TW)

(72) Inventors: CHI-MING TSAI, NEW TAIPEI CITY (TW); HAN-HSIN KUO, TAINAN CITY (TW); FU-MING HUANG, CHANGHUA COUNTY (TW); LIANG-GUANG CHEN, HSINCHU CITY (TW)

(73) Assignee: TAIWAN SEMICONDUCTOR MANUFACTURING COMPANY, LTD., Hsinchu (TW)

(21) Appl. No.: 14/037,916

(22) Filed: Sep. 26, 2013

(51) Int. Cl. H01L 21/02; H01L 21/321

(52) U.S. Cl. CPC H01L 21/02074; H01L 21/3212
USPC 451/73; 15/77; 134/6

(57) ABSTRACT

In a semiconductor wafer manufacturing apparatus, a rotation module is provided to hold the semiconductor wafer at a plane. The semiconductor wafer is revolved by the rotation module around a first axis. The first axis is substantially perpendicular to the plane. A cleaning module is configured to revolve around a second axis when the cleaning module contacts the surface of the semiconductor wafer. A mechanism is further provided to enable the rotation module and/or the cleaning module to move along a direction substantially perpendicular to the first axis. Consequently, the relative velocities at the contact points between the semiconductor wafer and the cleaning module are changed. Moreover, no relative velocity at any contact point between the semiconductor wafer and the cleaning module is zero or close to zero.

### FIELD

The present disclosure generally relates to an apparatus and method for manufacturing a semiconductor wafer.

### BACKGROUND

The semiconductor integrated circuit (IC) industry has experienced rapid growth. Advances in IC materials and design have produced generations of ICs where each generation has smaller and more complex circuits than the previous generations. However, these advances have increased the complexity of processing and manufacturing ICs. In order for these advances to be realized, developments in IC processing and manufacturing are needed.

To increase the yield of IC processing and manufacturing, a semiconductor wafer needs to undergo quite a few process stages. One of the process stages is the chemical mechanical polishing (CMP) process. The chemical mechanical polishing process is usually conducted by a specifically designed apparatus. Within such apparatus, the semiconductor wafer is mechanically polished in conjunction with chemical slurry. Residues, either from the slurry or the environment, are often observed on semiconductor wafer surface after polish (post-CMP). The residues are required to be removed from the semiconductor wafer surface in order to reduce the defect density. Thus, ways to improve cleaning efficiency of post-CMP residues are continuingly being sought.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A and 1B are different perspective views of a semiconductor manufacturing apparatus in accordance with some embodiments of the present disclosure.

FIGS. 2A-2E are different perspective views of a semiconductor manufacturing apparatus in accordance with some embodiments of the present disclosure.

FIGS. 3A-3C are different perspective views of a semiconductor manufacturing apparatus in accordance with some embodiments of the present disclosure.

FIGS. 4A-4E are different perspective views of a semiconductor manufacturing apparatus in accordance with some embodiments of the present disclosure.

FIG. 5 is a semiconductor wafer chemical mechanical polishing apparatus in accordance with some embodiments of the present disclosure.

FIG. 6 is a semiconductor wafer manufacturing method in accordance with some embodiments of the present disclosure.

Like reference symbols in the various drawings indicate like elements.

### DETAILED DESCRIPTION OF THE DISCLOSURE

Embodiments, or examples, of the disclosure illustrated in the drawings are now described using specific languages. It will nevertheless be understood that no limitation of the scope of the disclosure is thereby intended. Any alterations and modifications in the described embodiments, and any further applications of principles described in this document are contemplated as would normally occur to one of ordinary skill in the art to which the disclosure relates. Reference numbers may be repeated throughout the embodiments, but this does not necessarily require that feature(s) of one embodiment apply to another embodiment, even if they share the same reference number. It will be understood that when an element is referred to as being “connected to” or “coupled to” another element, it may be directly connected to or coupled to the other element, or intervening elements may be present.

Uniformity of residue removal in post-CMP cleaning has been an issue for semiconductor wafer cleaning processes. The post-CMP cleaning is designed to remove at least the residual slurry particles and other chemical contaminants introduced during CMP process by the slurries, pads, and conditioning tools. In the present disclosure, an apparatus of manufacturing a semiconductor wafer is provided to remove post-CMP residues. The uniformity of cleaning efficiency is reduced to evenly remove residues from the semiconductor wafer. Some dead zones, i.e., where the cleaning velocity is zero or close to zero, on the semiconductor wafer surface during a post-CMP cleaning operation are avoided by configuring a cleaning unit in a CMP tool. In some embodiments, the dead zones are located around the wafer center, and the cleaning unit is configured to change the cleaning velocity about the center of the semiconductor wafer surface. Moreover, a method of manufacturing a semiconductor wafer is conducted by using the apparatus in order to effectively clean a post-polish semiconductor wafer surface during a CMP operation.

### Semiconductor Manufacturing Apparatus

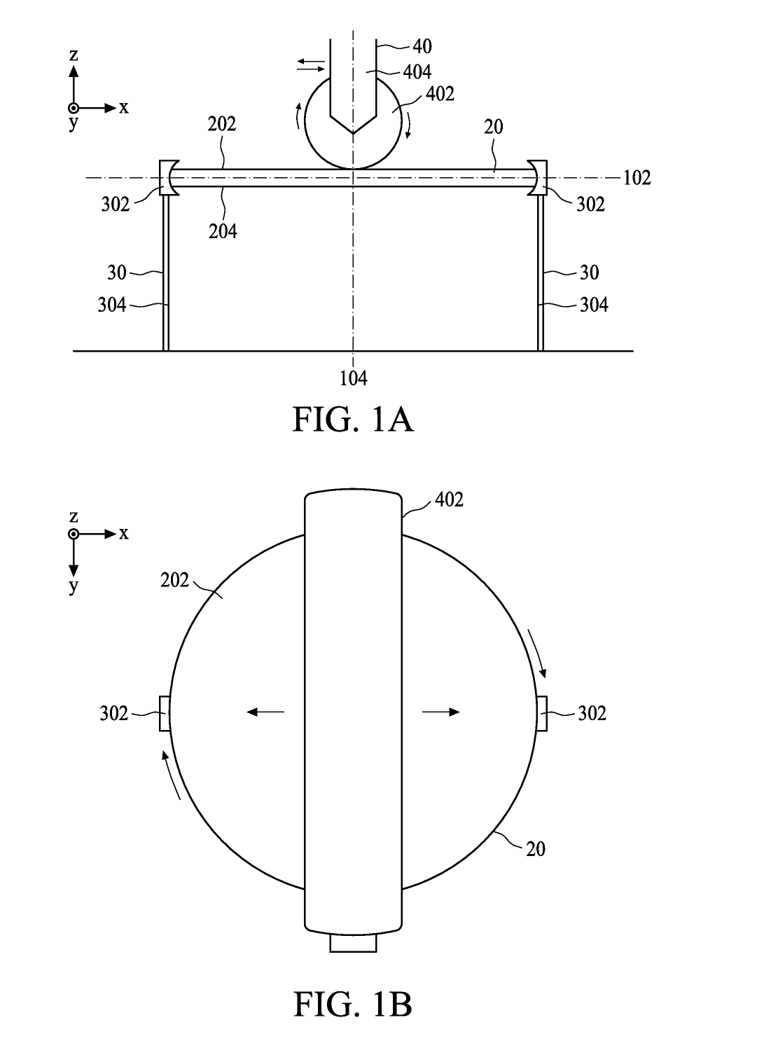

FIGS. 1A and 1B are different perspective views of a semiconductor manufacturing apparatus in accordance with some embodiments of the present disclosure.

FIG. 1A is a side-view of the semiconductor manufacturing apparatus in accordance with some embodiments of the present disclosure. FIG. 1B is a top-view of the semiconductor manufacturing apparatus in accordance with some embodiments of the present disclosure. A semiconductor wafer 20 is held by a rotation module 30. The rotation module maintains the semiconductor wafer 20 at a predetermined plane 102. A diameter of the semiconductor wafer 20 is about 12 inches. Wafer of other sizes are within the contemplated scope of the present disclosure. The semiconductor wafer 20 is driven by the rotation module 30 to revolve around a first axis 104. The first axis 104 is substantially perpendicular to the plane 102. In other words, the first axis 104 is substantially parallel with the z-axis. The plane 102 is substantially parallel with the plane formed by the x-axis and the y-axis. In addition, a cleaning module 40 is configured to revolve around the y-axis. The revolving of the semiconductor wafer 20 as well as the cleaning module 40 create a relative velocity, i.e., a cleaning velocity, at a contact point between the semiconductor wafer 20 and the cleaning module 40. Such relative velocity helps to remove the residues from the CMP-process on the surface of the semiconductor wafer 20. In some embodiments, the cleaning module 40 is configured to move along directions (the arrow heads which are substantially parallel with the x-axis) substantially perpendicular to the z-axis. Such movements help to change the relative velocities at contact points between the semiconductor wafer 20 and the cleaning module 40. The movement of the cleaning module 40 changes the relative velocities of such contact points from zero to not zero, or from close to zero to not close to zero. Accordingly, residues from the CMP process on the semiconductor wafer 20 are removed more thoroughly and uniformly.

Referring to FIG. 1A, in some embodiments in accordance with the present disclosure, the semiconductor wafer 20 has a first surface 202 and an opposing second surface 204. The first surface 202 is the front side of the semiconductor wafer 20 and the second surface 204 is the back side of the semiconductor wafer 20. In other words, the first surface 202 is a patterned surface of the semiconductor wafer 20. In certain embodiments in accordance to the present disclosure, the second surface 204 is a patterned surface of the semiconductor wafer 20.

Referring to FIG. 1A, in some embodiments in accordance with the present disclosure, the rotation module 30 includes at least two knobs 302 for holding the semiconductor wafer 20. The knobs 302 are supported by levers 304. The levers 304, in combination with the knobs 302, are configured to maintain the semiconductor wafer 20 at the plane 102. In certain embodiments, the knobs 302 are configured to clamp the edge of the semiconductor wafer 20 so as to hold the semiconductor wafer 20. At least one of the knobs 302 is configured to spin. The spinning of the knobs 302 induces the semiconductor wafer 20 to revolve around the z-axis on the plane 102.

Referring to FIG. 1A, in some embodiments in accordance with the present disclosure, the cleaning module 40 includes a brush 402. The brush 402 is made of porous polymers or polyvinyl alcohol (PVA). An arm 404 is coupled to the brush 402 in order to control the position of and revolve the brush 402. With reference to FIG. 1B, the brush 402 is in a cylindrical shape. A diameter of the brush is between about 4 centimeters and about 10 centimeters. Brush of other sizes and shapes are within the contemplated scope of the present disclosure. The brush 402 is configured to revolve around the y-axis. The arm 404 positions the revolving brush 402 to be in contact with the first surface 202 of the revolving semiconductor wafer 20. Accordingly, a relative velocity at the contact points between the semiconductor wafer 20 and the brush 402 is created. In addition, as illustrated in FIGS. 1A and 1B, the arm 404 is configured to move the brush 402 in directions substantially parallel with the x-axis. Such movement of the brush 402 changes the relative velocity at the contact points between the semiconductor wafer 20 and the brush 402. Consequently, the relative velocity at any contact point between the semiconductor wafer 20 and the brush 402 is not zero or close to zero. Moreover, the relative velocities at contact points near the center of the semiconductor wafer 20 between the semiconductor wafer 20 and the brush 402 are not zero or close to zero.

It is to be noted that in some embodiments, a pressure is applied by the arm 404 through the brush 402 to the semiconductor wafer 20. Depending on the degree of the pressure, the revolving velocity of the semiconductor wafer 20 and/or the brush 402 may be changed. In some embodiments, the degree of pressure of the brush 402 against the semiconductor wafer 20 is between about 0 and about 30 Newton (N). In certain embodiments, the degree of pressure of the brush 402 against the semiconductor wafer 20 is between about 0 and about 20 Newton (N). For example, if a higher pressure is applied to the semiconductor wafer 20, the brush 402 may be moved in a lower velocity, and still renders any relative velocity between the semiconductor wafer 20 and the brush 402 not zero or close to zero. In another example, a higher pressure applied to the semiconductor wafer 20 renders a more thorough and more uniform residue removal.

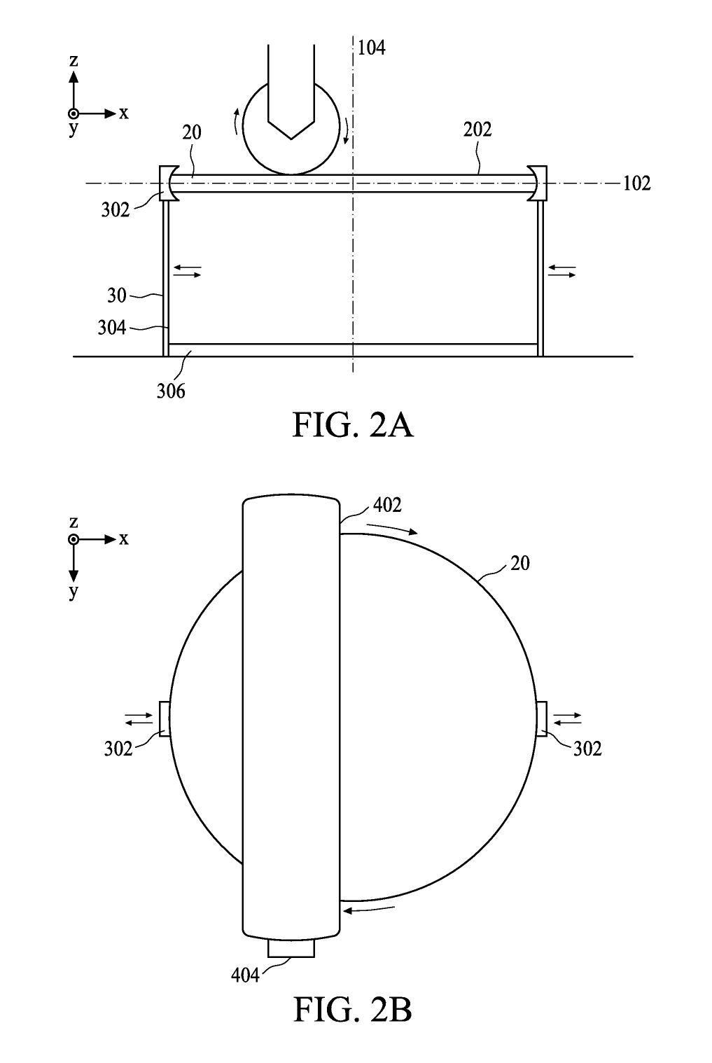

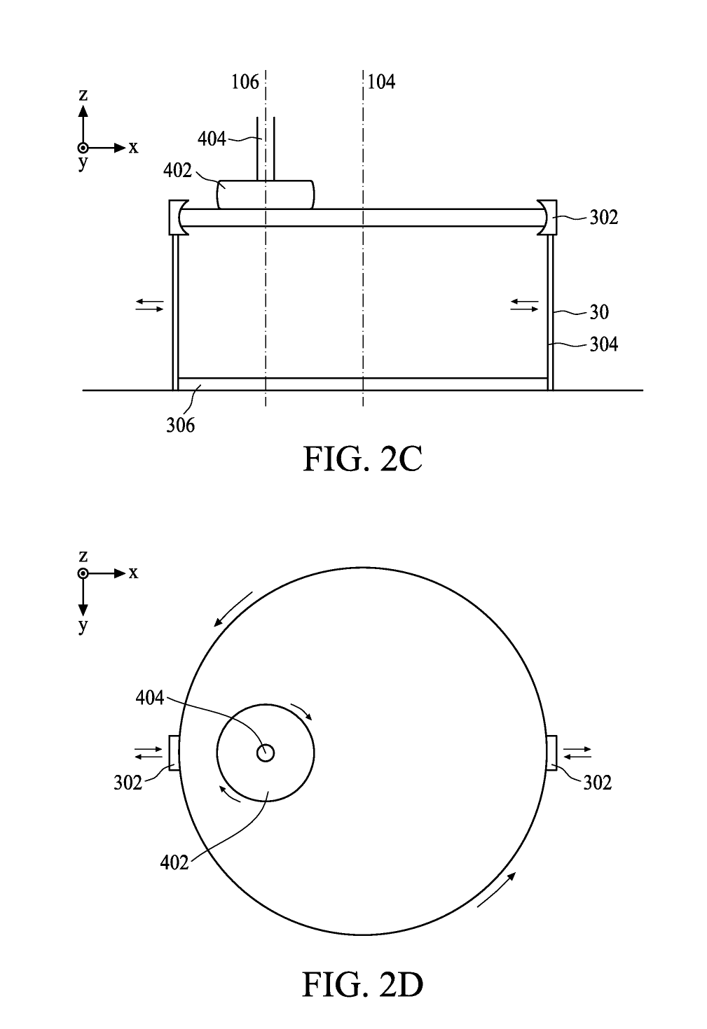

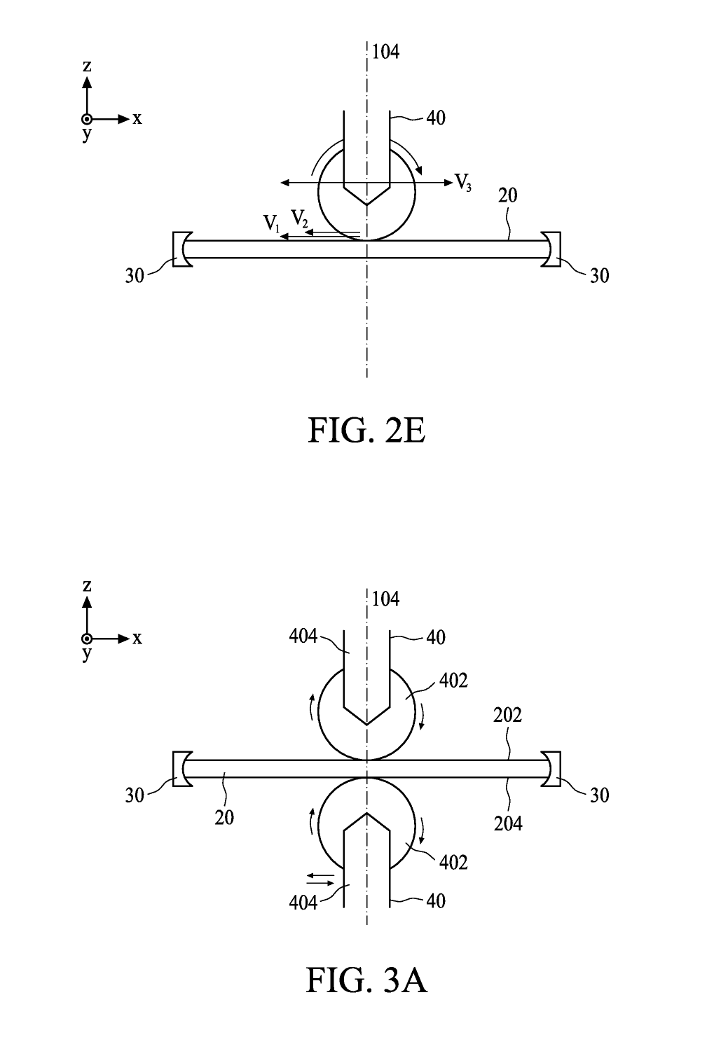

FIGS. 2A-2E are different perspective views of a semiconductor manufacturing apparatus in accordance with some embodiments of the present disclosure.

FIG. 2A is a side-view of the semiconductor manufacturing apparatus in accordance with some embodiments of the present disclosure. The rotation module 30 is configured to move along directions (the arrow heads which are substantially parallel with the x-axis) substantially parallel with the plane formed by the x-axis and the y-axis. In addition, the cleaning module 40 is configured to maintain in contact with a predetermined position of the semiconductor wafer 20. The rotation module 30 has a base 306. The base 306 is equipped with a motor, a cylinder, a screw, or combinations thereof (not depicted) so as to provide the rotation module 30 movement along directions substantially perpendicular to the first axis 104. The base 306 is configured to provide the rotation module 30 a linear or non-linear movement. For example, the rotation module 30 may be in rotary movements at a plane substantially parallel with the plane formed by the x-axis and the y-axis. Exemplary mechanisms configured to provide movement to the rotation module 30 include a linear motor, an air cylinder, or a ball screw. In certain embodiments, the rotation module 30 does not have a base. Each of the levers 304 is connected to a motor, a cylinder, a screw, or combinations thereof respectively. Accordingly, the levers 304 are configured to move in conjunction in one direction simultaneously to move the rotation module 30.

FIG. 2B is a top-view of the semiconductor manufacturing apparatus in accordance with some embodiments of the present disclosure. When in contact with the brush 402, the semiconductor wafer 20 is moved substantially parallel with the plane formed by the x-axis and the y-axis. In one embodiment, the semiconductor wafer 20 is moved along directions substantially parallel with the x-axis. The rotation of the semiconductor wafer 20 and the brush 402, as well as the movement of the rotation module 30 ensure that no relative velocity at any contact point between the semiconductor wafer 20 and the brush 402 is zero or close to zero.

FIG. 2C is a side-view of the semiconductor manufacturing apparatus in accordance with some embodiments of the present disclosure. The rotation module 30 is configured to move along directions substantially parallel with the x-axis. In addition, the brush 402 is configured to revolve around a second axis 106, which is substantially parallel with the first axis 104. In other words, the second axis 106 is substantially parallel with the z-axis. FIG. 2D is a top-view of the semiconductor manufacturing apparatus in accordance with one of the embodiments in FIG. 2C. The revolving direction of the semiconductor wafer 20 and the brush 402 may be opposite. In one embodiment, the brush 402 is configured to revolve clockwise and the semiconductor wafer 20 is configured to revolve counter-clockwise.

Referring to FIG. 2E, the rotation of the semiconductor wafer 20 itself creates a first tangential velocity V1 at a location on the semiconductor wafer 20. The first tangential velocity V1 is acquired by multiplying the rotation velocity of the semiconductor wafer 20 by the distance between the location and the center of the semiconductor wafer 20. Accordingly, the first tangential velocity at a location closer to the edge of the semiconductor wafer 20 is larger than that at a location close to the center of the semiconductor wafer 20. In other words, the first tangential velocity V1 is proportional to the distance between the location and the center of the semiconductor wafer 20. In addition, the brush 402 is configured to revolve while in contact with the semiconductor wafer 20. Consequently, a second tangential velocity V2 is created at the contact point between the brush 402 and the semiconductor wafer 20. Furthermore, the cleaning module 40 is configured to move along directions substantially parallel with the plane formed by the x-axis and the y-axis at a third velocity V3. The combination of the first tangential velocity V1, the second tangential velocity V2 and the third velocity V3 creates a relative velocity (not depicted), i.e., a cleaning velocity, at a contact point between the semiconductor wafer 20 and the cleaning module 40. Movements of the semiconductor wafer 20 and the cleaning module 40 are controlled such that no cleaning velocity is zero or close to zero. It is to be noted that the third velocity V3 may be created by the movement of the rotation module 20 along directions substantially parallel with the plane formed by the x-axis and the y-axis. In some embodiments, the third velocity V3 is created conjunctively by the movements of the cleaning module 40 and the rotation module 30 along directions substantially parallel with the plane formed by the x-axis and the y-axis.

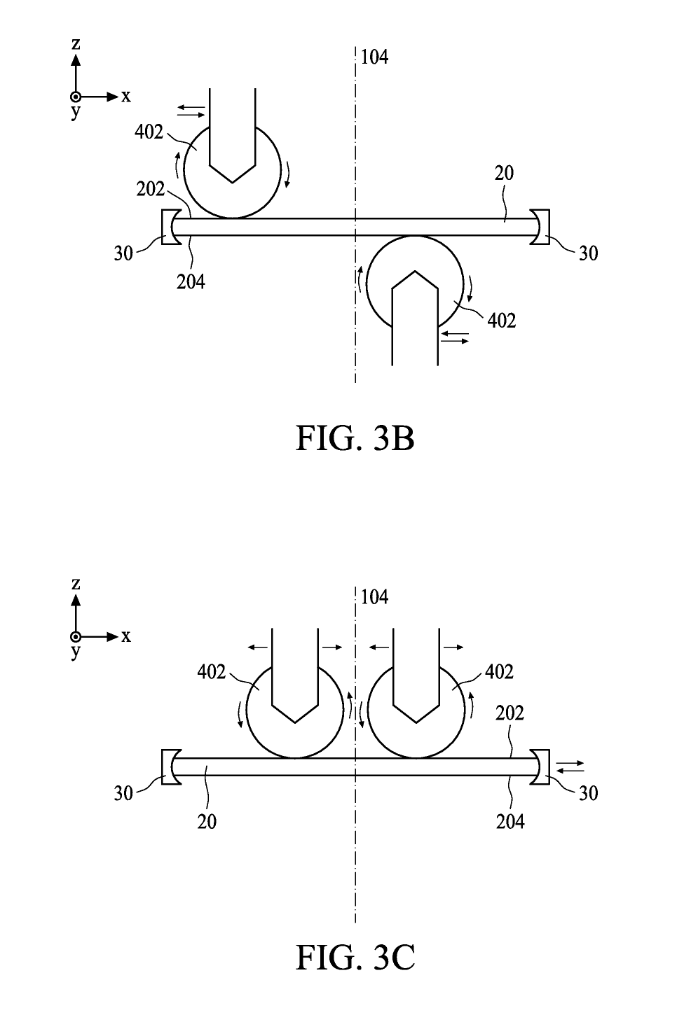

FIGS. 3A-3C are different perspective views of a semiconductor manufacturing apparatus in accordance with some embodiments of the present disclosure.

FIG. 3A is a side-view of the semiconductor manufacturing apparatus in accordance with some embodiments of the present disclosure. The semiconductor wafer 20 is held and revolved by the rotation module 30. Detailed technical features of the rotation module 30 have been disclosed in the previous disclosures and therefore will not be repeated. A cleaning module 40 with two brushes 402 is provided. The two brushes 402 are configured to be in contact with the first surface 202 and the second surface 204 of the semiconductor wafer 20 respectively. In addition, at least one of the brushes 402 is configured to maintain in contact with a predetermined position of the semiconductor wafer 20. In other words, at least one of the brushes 402 is configured to move along directions substantially perpendicular to the z-axis. The movement of at least one of the brushes 402 is achieved by equipping the cleaning module 40 with a motor, a cylinder, a screw, or combinations thereof (not depicted). It is to be noted that the movement of at least one of the brushes 402 may be linear, rotary or in any direction so as to change the relative velocities of the contact points between the semiconductor wafer 20 and the brush 402.

FIG. 3B is a side-view of the semiconductor manufacturing apparatus in accordance with some embodiments of the present disclosure. A cleaning module 40 with two brushes 402 is provided. The two brushes 402 are in contact with the first surface 202 and the second surface 204 of the semiconductor wafer 20 respectively. Both of the brushes 402 are configured to move along directions substantially perpendicular to the z-axis, although the brushes 402 may not move in the same direction simultaneously. In one embodiment, the brushes 402 are configured to be in contact with asymmetric portions of the first surface 202 and the second surface 204 simultaneously while cleaning the semiconductor wafer 20.

FIG. 3C is a side-view of the semiconductor manufacturing apparatus in accordance with some embodiments of the present disclosure. A cleaning module 40 with two brushes 402 is provided. The two brushes 402 are in contact with the first surface 202 of the semiconductor wafer 20 simultaneously. The two brushes 402 are moveable along directions substantially perpendicular to the z-axis. In addition, the rotation module 30, along with the semiconductor wafer 20, are configured to move along the direction substantially perpendicular to the z-axis.

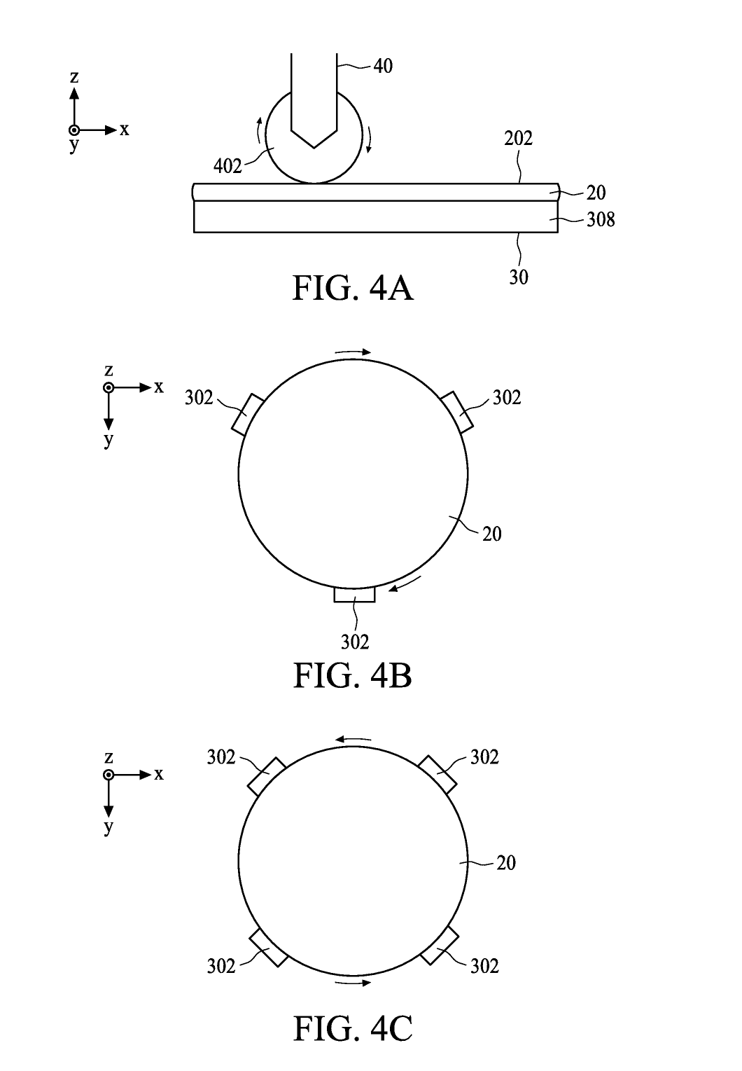

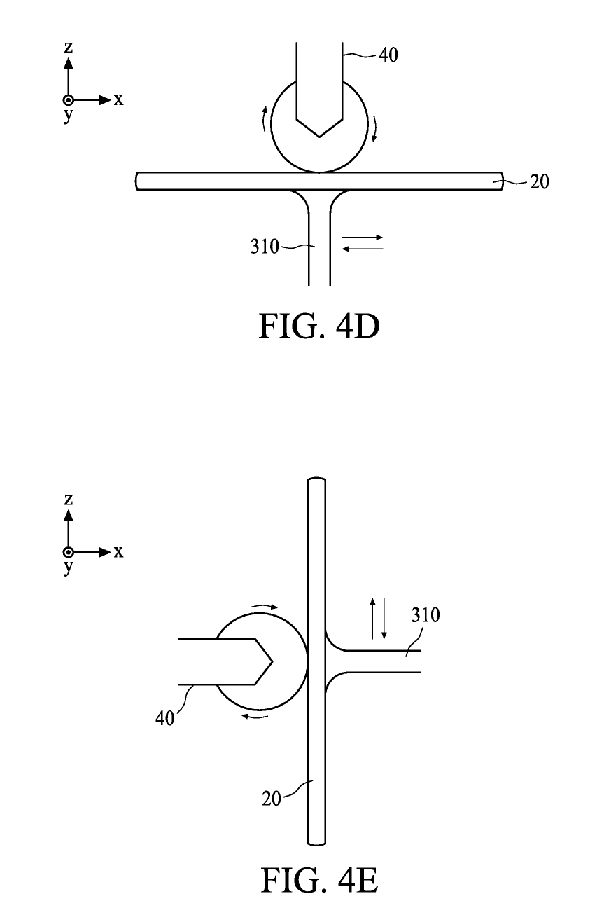

FIGS. 4A-4E are different perspective views of a semiconductor manufacturing apparatus in accordance with some embodiments of the present disclosure.

FIG. 4A is a side-view of the semiconductor manufacturing apparatus in accordance with some embodiments of the present disclosure. The semiconductor wafer 20 is attached to a rotation base 308 of the rotation module 30. The semiconductor wafer 20 may be secured to the rotation base 308 by means of vacuum, adhesive or other suitable mechanisms known to persons having ordinary skill in the art. The rotation base 308 is configured to spin so as to revolve the semiconductor wafer 20. The brush 402 is configured to revolve while in contact with the first surface 202 of the semiconductor wafer 20 so as to change the relative velocities at contact points between the semiconductor wafer 20 and the brush 402. Other technical features of the rotation module 30 and the cleaning module 40 have been disclosed in the previous disclosure and therefore will not be repeated.

FIGS. 4B-4C are top-views of the semiconductor manufacturing apparatus in accordance with some embodiments of the present disclosure. The cleaning module 40 is omitted in FIGS. 4B-4C for clearer views of the knobs 302. Referring to FIG. 4B, a rotation module 30 with three knobs 302 is provided. The knobs are 302 arranged in substantially triangular. Referring to FIG. 4C, a rotation module 30 with four knobs 302 is provided. The knobs are 302 arranged in substantially quadrilateral. At least one of the knobs 302 is configured to spin so as to induce the rotation of the semiconductor wafer 20. In certain embodiments, the rotation module 30 may have more than four knobs (not depicted) as a person having ordinary skill in the art would deem suitable. The more than four knobs may be arranged in substantially polygonal.

FIGS. 4D-4E are a side-views of the semiconductor manufacturing apparatus in accordance with some embodiments of the present disclosure. Referring to FIG. 4D, a rotation module 30 equipped with a vacuum chuck 310 is provided. The vacuum chuck 310 is configured to secure the semiconductor wafer 20 on the vacuum chuck 310 when the rotation module 30 revolves the semiconductor wafer 20. No knobs are provided to clamp the edge of the semiconductor wafer 20. In certain embodiments, knobs are provided to clamp the edge of the semiconductor wafer 20 to change rotation velocity, enhance steadiness of the revolving semiconductor wafer 20, or for any reason foreseeable by a person having ordinary skill in the art. Referring to FIG. 4E, a rotation module 30 equipped with a vacuum chuck 310 is provided. The vacuum chuck 310 enables the semiconductor wafer 20 to be positioned substantially parallel with a plane formed by the y-axis and the z-axis. In other words, the semiconductor wafer 20 is positioned substantially perpendicular to the x-axis while revolving.

### Semiconductor Wafer Chemical Mechanical Polishing Apparatus

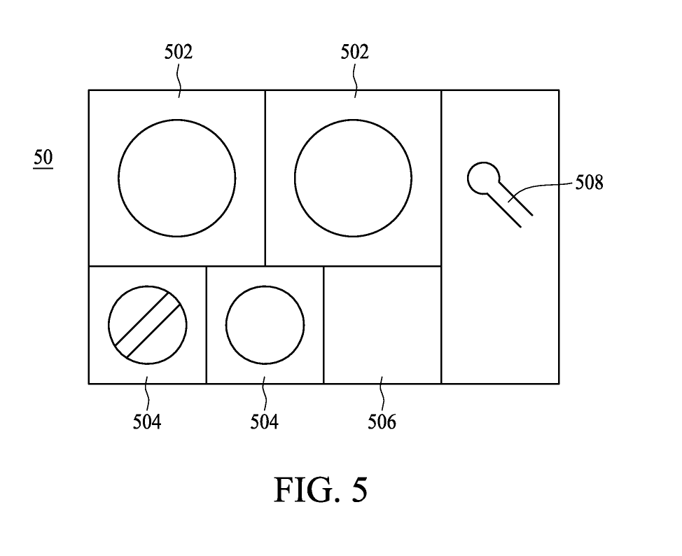

FIG. 5 is a semiconductor wafer chemical mechanical polishing apparatus in accordance with some embodiments of the present disclosure.

Referring to FIG. 5, the semiconductor wafer chemical mechanical polishing apparatus 50 has a chemical mechanical polishing unit 502, an in-situ cleaning unit 504, a dryer 506 and a conveyer 508. A semiconductor wafer (not depicted) is conveyed between the chemical mechanical polishing unit 502, the in-situ cleaning unit 504 and the dryer 506 by the conveyer 508.

In some embodiments in accordance with the present disclosure, the chemical mechanical polishing unit 502 is configured to chemically mechanically polish the semiconductor wafer. The polishing process is configured to remove the surface topologies and smoothes and flattens the surface of the semiconductor wafer. The chemical mechanical polishing unit 502 includes a polishing pad, a pad conditioner, a slurry dispenser and a semiconductor wafer holder (not depicted). The wafer holder is configured to push the semiconductor wafer against the polishing pad. The slurry dispenser is configured to dispense slurries between the semiconductor wafer and the polishing pad. The polishing pad is configured to create mechanical abrasion and chemical etch to the semiconductor wafer. Accordingly, defect or residues on the semiconductor wafer surface is removed. The pad conditioner is configured to maintain the surface condition of the polishing pad so as to maintain the uniformity of the polishing results of the chemical mechanical polishing unit 502.

In some embodiments in accordance with the present disclosure, the in-situ cleaning unit 504 is configured to clean the residues on the semiconductor wafer surface from the CMP process. The in-situ cleaning unit 504 is configured to remove the residual slurry particles and other chemical contaminants introduced during the chemical mechanical polishing process by the slurries, the polishing pad, and the pad conditioner. The in-situ cleaning unit 504 includes a cleaning module and a rotation module. Technical features of the cleaning module and the rotation module have been disclosed in the previous paragraphs and will not be repeated.

In some embodiments in accordance with the present disclosure, the dryer 506 is configured to remove the moisture from the post-CMP semiconductor wafer surface. In certain embodiments, the dryer 506 is configured to spin-dry the semiconductor wafer. In some embodiments, the dryer 506 is an IPA (isopropyl alcohol) dryer. It is to be noted that an IPA dryer may be a vertical type, a horizontal type, or any type that a person having ordinary skill in the art would deem fit.

In some embodiments in accordance with the present disclosure, the conveyer 508 is configured to convey the semiconductor wafer between the chemical mechanical polishing unit 502, the in-situ cleaning unit 504 and the dryer 506 by the conveyer 508. The conveyer may include a clamping device or a vacuuming device to secure the semiconductor from departing the conveyer during conveyance.

### Semiconductor Wafer Manufacturing Method

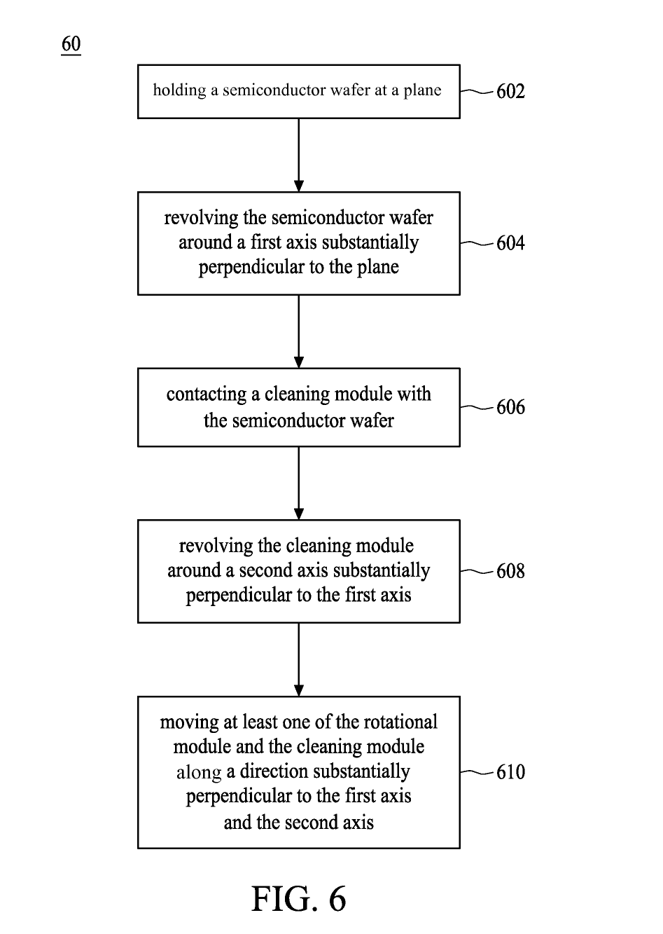

FIG. 6 is a semiconductor wafer manufacturing method in accordance with some embodiments of the present disclosure.

Referring to FIG. 6, in operation 602, a rotation module holds a semiconductor wafer at a plane. The rotation module does so by utilizing a knob, a vacuum chuck, or combinations thereof. In operation 604, the rotation module revolves the semiconductor wafer around a first axis. The first axis is substantially perpendicular to the plane. In one embodiment, the first axis is substantially parallel with the z-axis in a Cartesian coordinate system. The rotation module does so by utilizing the knob, the vacuum chuck, or combinations thereof. The semiconductor wafer is revolved at an rpm between about 30 and about 300 around the z-axis.

In operation 606, a cleaning module is configured to be in contact with the semiconductor wafer. In operation 608, the cleaning module is configured to revolve around the y-axis while in contact with the semiconductor wafer. The cleaning module is revolved at an rpm between about 30 and a about 300 around the y-axis.

In operation 610, at least one of the rotation module and the cleaning module is moved along directions substantially parallel with the plane formed by the x-axis and the y-axis. Such movement of the rotation module and/or the cleaning module renders the relative velocities at the contact points between the semiconductor wafer and the cleaning module not zero or not close to zero. Such movements are achieved by equipping the rotation module and/or the cleaning module with a motor, a cylinder, a screw or combinations thereof.

In some embodiments in accordance to the present disclosure, the duration that the cleaning module is in contact with the semiconductor wafer is between about 10 seconds and about 180 seconds.

The present disclosure provides an apparatus and method for manufacturing semiconductor wafer. In some embodiments of the present disclosure, an apparatus including a rotation module and a cleaning module is provided. During manufacture, the rotation module holds a semiconductor wafer at a plane and revolves the semiconductor wafer around a first axis perpendicular to the plane. The cleaning module is rotatively in contact with the front side of the semiconductor wafer. The rotation module and/or the cleaning module are moved along a direction perpendicular to the first axis. Accordingly, a relative velocity, i.e., cleaning velocity, is created at any contact point between the semiconductor wafer and the cleaning module. Moreover, the cleaning velocity is not zero or close to zero.

The present disclosure further provides a semiconductor wafer chemical mechanical polishing apparatus. The apparatus has a chemical mechanical polishing unit, an in-situ cleaning unit, a dryer, and a conveyer. The conveyer is configured to convey a semiconductor wafer between the chemical mechanical polishing unit, the in-situ cleaning unit and the dryer. The chemical mechanical polishing unit is configured to chemically mechanically polish the semiconductor wafer. The in-situ cleaning unit has a rotation module, which is configured to hold the semiconductor wafer at a plane. The rotation module further revolves the semiconductor wafer around a first axis substantially perpendicular to the plane so as to create a first tangential velocity at a location on the semiconductor wafer. The first tangential velocity is proportional to a distance between the location and a center of the semiconductor wafer. The in-situ cleaning unit further has a cleaning module, which is configured to revolve around a second axis substantially perpendicular to the first axis. The rotation of the cleaning module creates a second tangential velocity at a contact point between the semiconductor wafer and the cleaning module. In addition, the rotation module and/or the cleaning module is configured to move along a direction substantially perpendicular to the first axis and substantially perpendicular to the second axis at a third velocity. Consequently, a relative velocity between the semiconductor wafer and the cleaning module at the center or close to the center of the semiconductor wafer is not zero or close to zero. The dryer is configured to dry the semiconductor treated by the chemical mechanical polishing unit and/or the in-situ cleaning unit.

The present disclosure further provides a semiconductor wafer manufacturing method. A semiconductor wafer is held by a rotation module at a plane. The rotation is configured to revolve the semiconductor wafer around a first axis substantially perpendicular to the plane. A cleaning module is configured to contact the semiconductor wafer. The cleaning module is configured to revolve around a second axis substantially perpendicular to the first axis. In addition, the rotation module and/or the cleaning module is moved along a direction substantially perpendicular to the first axis and substantially perpendicular to the second axis, so as to change the relative speeds at contact points between the semiconductor wafer and the cleaning module.

Although the present invention and its advantages have been described in detail, it should be understood that various changes, substitutions and alterations cancan be made herein without departing from the spirit and scope of the invention as defined by the appended claims. For example, many of the processes discussed above cancan be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor wafer manufacturing apparatus, comprising:
a rotation module configured to hold a semiconductor wafer at a plane and revolve the semiconductor wafer around a first axis substantially perpendicular to the plane; and
a cleaning module configured to be in contact with the semiconductor wafer and revolve around a second axis,
wherein at least one of the rotation module and the cleaning module is configured to move along a direction substantially perpendicular to the first axis.

2. The semiconductor wafer manufacturing apparatus according to claim 1, wherein the rotation module comprises at least two knobs configured to clamp an edge of the semiconductor wafer.

3. The semiconductor wafer manufacturing apparatus according to claim 2, wherein at least one of the at least two knobs is configured to spin so as to revolve the semiconductor wafer.

4. The semiconductor wafer manufacturing apparatus according to claim 1, wherein the rotation module comprises a vacuum chuck, and the vacuum chuck is configured to secure the semiconductor wafer on the vacuum chuck.

5. The semiconductor wafer manufacturing apparatus according to claim 1, wherein the cleaning module comprises a brush configured to be in contact with a patterned surface of the semiconductor wafer.

6. The semiconductor wafer manufacturing apparatus according to claim 1, wherein the cleaning module comprises a first brush and a second brush, the first brush and the second brush are configured to contact opposite surfaces of the semiconductor wafer.

7. The semiconductor wafer manufacturing apparatus according to claim 6, wherein one of the first brush and the second brush is configured to maintain in contact with a predetermined position of the semiconductor wafer.

8. The semiconductor wafer manufacturing apparatus according to claim 1, wherein the rotation module is configured to move along the direction substantially perpendicular to the first axis by means of a motor, a cylinder, a screw or combinations thereof.

9. The semiconductor wafer manufacturing apparatus according to claim 1, wherein the cleaning module is configured to move along the direction substantially perpendicular to the first axis by means of a motor, a cylinder, a screw or combinations thereof.

10. The semiconductor wafer manufacturing apparatus according to claim 1, wherein the second axis is substantially parallel with the first axis.

11. The semiconductor wafer manufacturing apparatus according to claim 1, wherein the second axis is substantially perpendicular to the first axis.

12. A semiconductor wafer chemical mechanical polishing apparatus, comprising:
a chemical mechanical polishing unit;
an in-situ cleaning unit comprising:
a rotation module configured to hold a semiconductor wafer at a plane and revolve the semiconductor wafer around a first axis substantially perpendicular to the plane so as to create a first tangential velocity at a location on the semiconductor wafer, wherein the first tangential velocity is proportional to a distance between the location and a center of the semiconductor wafer; and
a cleaning module configured to revolve around a second axis substantially perpendicular to the first axis so as to create a second tangential velocity at a contact point between the semiconductor wafer and the cleaning module,
wherein at least one of the rotation module and the cleaning module is configured to move along a direction substantially perpendicular to the first axis and substantially perpendicular to the second axis at a third velocity,
wherein a relative velocity between the semiconductor wafer and the cleaning module at a center of the semiconductor wafer is not zero,
a dryer; and
a conveyer configured to transmit the semiconductor wafer between the chemical mechanical polishing unit, the in-situ cleaning unit, and the dryer.

13. The semiconductor wafer chemical mechanical polishing apparatus according to claim 12, wherein the dryer includes isopropyl alcohol dryer.

14. The semiconductor wafer chemical mechanical polishing apparatus according to claim 12, wherein the rotation module comprises a plurality of knobs configured to clamp an edge of the semiconductor wafer, and the plurality of knobs are arranged in substantially triangular, substantially quadrilateral or substantially polygonal.

15. The semiconductor wafer chemical mechanical polishing apparatus according to claim 12, wherein the cleaning module comprises a brush made of porous polymers or polyvinyl alcohol.

16. The semiconductor wafer chemical mechanical polishing apparatus according to claim 12, wherein the cleaning module comprises two brushes and the two brushes are configured to be in contact with opposite surfaces of the semiconductor wafer asymmetrically.

17. A semiconductor wafer manufacturing method, comprising:
holding a semiconductor wafer at a plane;
revolving the semiconductor wafer around a first axis substantially perpendicular to the plane;
contacting a cleaning module with the semiconductor wafer;
revolving the cleaning module around a second axis substantially perpendicular to the first axis; and
moving at least one of the semiconductor wafer and the cleaning module along a direction substantially perpendicular to the first axis and substantially perpendicular to the second axis.

18. The semiconductor wafer manufacturing method according to claim 17, further comprises:
revolving the semiconductor wafer around the first axis at an rpm between about 30 and about 300.

19. The semiconductor wafer manufacturing method according to claim 17, further comprises:
revolving the cleaning module around the second axis at an rpm between about 30 and about 300.

20. The semiconductor wafer manufacturing method according to claim 17, wherein the cleaning module is configured to contact the semiconductor wafer for about 10 seconds to about 180 seconds.
